(19) United States
(12) Patent Application Publication
(10) Pub. No.: US 2015/0179787 A1
(43) Pub. Date: Jun. 25, 2015

(54) GROUP III-V SEMICONDUCTOR TRANSISTOR AND METHOD OF MANUFACTURING THE SAME

(71) Applicant: Samsung Electronics Co., Ltd., Suwon-Si (KR)

(72) Inventors: Young-jin CHO, Seoul (KR); Tae-Joo PARK, Ansan-si (KR); Dong-Soo LEE, Gunpo-si (KR); Myoung-Jae LEE, Hwaseong-si (KR); Seong-ho CHO, Gwacheon-si (KR)

(73) Assignee: Industry-University Cooperation Foundation Hanyang University ERICA Campus, Ansan-si (KR)

(21) Appl. No.: 14/577,478

(22) Filed: Dec. 19, 2014

(30) Foreign Application Priority Data
Dec. 20, 2013 (KR) 10-2013-0160672

(51) Int. Cl. H01L 29/78; H01L 21/02; H01L 29/423; H01L 29/20; H01L 29/51; H01L 29/66

(52) U.S. Cl. CPC H01L 29/785; H01L 29/517; H01L 29/66795; H01L 29/42364; H01L 29/20; H01L 21/02543; H01L 21/02546; H01L 21/02549; H01L 21/02178; H01L 21/02181; H01L 21/02255

(57) ABSTRACT

Provided are group III-V semiconductor transistors and methods of manufacturing the same. The method includes forming a group III-V semiconductor channel layer on a substrate, forming a gate insulating layer covering the group III-V semiconductor channel layer, and forming a protection layer including sulfur between the group III-V semiconductor channel layer and the gate insulating layer by annealing the substrate under a sulfur atmosphere.

### RELATED APPLICATIONS

This application claims priority from Korean Patent Application No. 10-2013-0160672, filed on Dec. 20, 2013, in the Korean Intellectual Property Office, the disclosure of which is incorporated herein in its entirety by reference.

### BACKGROUND

1. Field

Example embodiments relate to semiconductor transistors having a protection layer that includes sulfur on a group III-V channel and methods of manufacturing the same.

2. Description of the Related Art

As the integration density of semiconductor devices increases, sizes of elements that constitute the semiconductor devices are reduced, and gaps between the elements are also reduced. For example, in the case of a transistor based on silicon (Si), the sizes of a source, a drain, and a gate therein are reduced, and gaps between the source, the drain and the gate are reduced. When the size of a gate is reduced, a length of a channel is also reduced. With the miniaturization of plate type transistors, a driving voltage thereof has been reduced to approximately 1 V. With the improvement in the structure of the plate type transistors, the driving voltage thereof may be reduced below 1 V, but there is a limit in reducing the driving voltage. For example, a fin field effect transistor (FinFET) may have a driving voltage of approximately 0.7 V.

In order to overcome the limit of the driving voltage, studies have been conducted to replace a channel material with a group III-V material.

However, due to unfavorable interface characteristics between the group III-V channel and a gate insulating layer, a switching characteristic of the FinFET may be degraded. In order to improve the interface characteristics, a solution that includes a sulfur component, such as (NH₄)₂S, is coated onto a surface of the group III-V channel by using a wet process.

However, a sulfur component that is coated on the group III-V channel is partly detached from the group III-V channel, and thus, the characteristic of the transistor is degraded. Also, since the coating is performed by using a wet process, the wet process is typically not suitable for mass production.

### SUMMARY

At least one example embodiment relates to semiconductor transistors having a protection layer that includes sulfur between a group III-V semiconductor channel layer and a gate insulating layer.

Additional example embodiments will be set forth in part in the description which follows and, in part, will be apparent from the description, or may be learned by practice of the presented example embodiments.

According to at least one example embodiment, a transistor includes a substrate, a group III-V semiconductor channel layer on the substrate, a protection layer on the group III-V semiconductor channel layer, the protection layer including sulfur, a gate insulating layer covering the protection layer, a gate electrode on the gate insulating layer, and a source electrode and a drain electrode that are respectively connected to both edges or sides of the group III-V semiconductor channel layer, wherein the protection layer is formed by combining a dangling bond of the group III-V semiconductor channel layer with the sulfur.

The group III-V semiconductor channel layer may include one of InGaAs, GaAs, InP, GaSb, and InSb.

The dangling bond may be formed on a surface of the group III-V semiconductor channel layer.

The gate insulating layer may include hafnium oxide or aluminum oxide.

The gate insulating layer may have a thickness in a range of about 10 Å to about 100 Å.

The group III-V semiconductor channel layer may have a fin shape.

The transistor may further include an insulating layer that is formed on the substrate and has a slit that exposes a surface of the substrate, and a buffer layer that fills the slit, wherein the group III-V semiconductor channel layer is vertically formed on the buffer layer and the protection layer, the gate insulating layer, and the gate electrode sequentially surround a top surface and both side surfaces of the group III-V semiconductor channel layer.

The transistor may further include an insulating layer and a buffer layer which are sequentially formed between the substrate and the group III-V semiconductor channel layer, wherein the protection layer, the gate insulating layer, and the gate electrode sequentially surround a top surface and both side surfaces of the group III-V semiconductor channel layer.

According to at least one example embodiment, a method of manufacturing a transistor includes forming a group III-V semiconductor channel layer on a substrate, forming a gate insulating layer that covers the group III-V semiconductor channel layer, forming a protection layer including sulfur between the group III-V semiconductor channel layer and the gate insulating layer by annealing the substrate under a sulfur atmosphere, forming a gate electrode on the gate insulating layer, and forming a source electrode and a drain electrode that respectively contact both edges or sides of the group III-V semiconductor channel layer.

The forming of the protection layer may include annealing the substrate in a chamber into which an H₂S gas and a carrier gas are supplied.

The forming of the protection layer may include combining sulfur that is separated from H₂S gas and that passes through the gate insulating layer with a dangling bond of the group III-V semiconductor channel layer.

### BRIEF DESCRIPTION OF THE DRAWINGS

These and/or other aspects will become apparent and more readily appreciated from the following description of the example embodiments, taken in conjunction with the accompanying drawings in which:

FIG. 1 is a schematic cross-sectional view of a group III-V semiconductor transistor according to example embodiments;

FIG. 2 is a graph showing thin film characteristics of a gate insulating layer and a channel layer of the group III-V semiconductor transistor according to example embodiments;

FIG. 3 is a schematic cross-sectional view of a group III-V semiconductor transistor according to example embodiments;

FIG. 4 is a cross-sectional view taken along line IV-IV′ of FIG. 3;

FIG. 5 is a schematic cross-sectional view of a group III-V semiconductor transistor according to example embodiments;

FIG. 6 is a cross-sectional view taken along line IV-IV′ of FIG. 5;

FIGS. 7A through 7G are cross-sectional views sequentially showing a method of manufacturing a group III-V semiconductor transistor according to example embodiments;

FIGS. 8A through 8D are cross-sectional views sequentially showing a method of manufacturing a group III-V semiconductor transistor according to example embodiments; and

FIGS. 9A through 9C are cross-sectional views sequentially showing a method of manufacturing a group III-V semiconductor transistor according to example embodiments.

### DETAILED DESCRIPTION

Reference will now be made in detail to example embodiments illustrated in the accompanying drawings. In the drawings, the thicknesses of layers and regions may be exaggerated for clarity. The example embodiments are capable of various modifications and may be embodied in many different forms. It will be understood that when an element is referred to as being “on,” “connected” or “coupled” to another element, it can be directly on, connected or coupled to the other element or intervening elements may be present. In contrast, when an element is referred to as being “directly on,” “directly connected” or “directly coupled” to another element, there are no intervening elements present. As used herein the term “and/or” includes any and all combinations of one or more of the associated listed items. Further, it will be understood that when a layer is referred to as being “under” another layer, it can be directly under or one or more intervening layers may also be present. In addition, it will also be understood that when a layer is referred to as being “between” two layers, it can be the only layer between the two layers, or one or more intervening layers may also be present.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

In the drawing figures, the dimensions of layers and regions may be exaggerated for clarity of illustration. Like reference numerals refer to like elements throughout. The same reference numbers indicate the same components throughout the specification.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein. As used herein, expressions such as “at least one of,” when preceding a list of elements, modify the entire list of elements and do not modify the individual elements of the list.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain example embodiments of the present description.

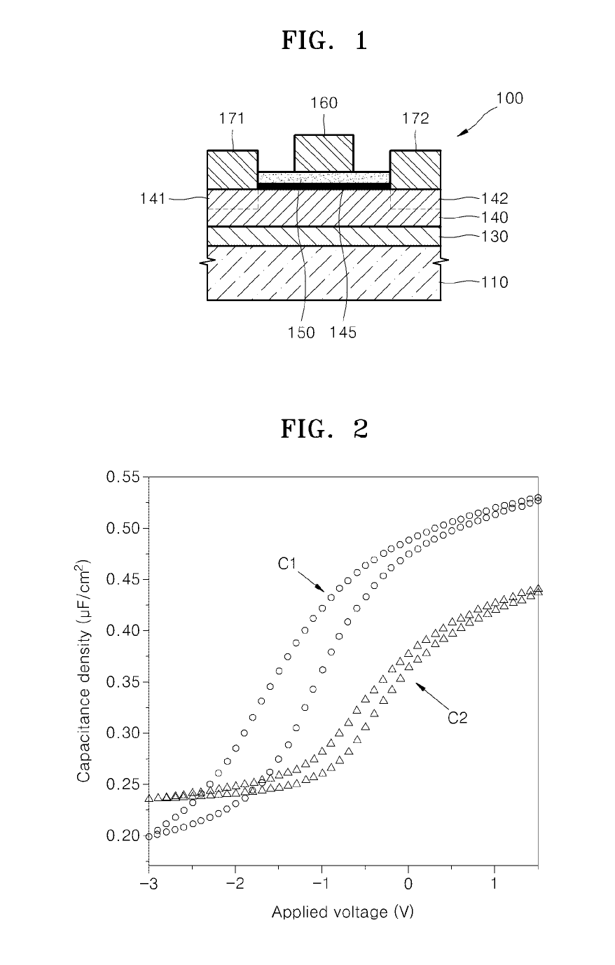

FIG. 1 is a schematic cross-sectional view of a group III-V semiconductor transistor 100 according to example embodiments.

Referring to FIG. 1, a buffer layer 130 and a channel layer 140 are sequentially formed on a substrate 110. A protection layer 145, a gate insulating layer 150, and a gate electrode 160 are sequentially formed on the channel layer 140. A source electrode 171 and a drain electrode 172 that are separated from each other are formed at both sides of the channel layer 140.

The substrate 110 may include silicon, which is mainly used in semiconductor processes. However, the current example embodiment is not limited thereto. That is, the substrate 110 may include one or more other semiconductor materials.

The buffer layer 130 may be epitaxially grown from the substrate 110 and may have the same lattice structure as the channel layer 140. The buffer layer 130 mitigates a lattice mismatch between the substrate 110 and the channel layer 140. The substrate 110 may be a silicon substrate having a (100) surface, and the buffer layer 130 may also have a cubic-lattice structure like the silicon substrate. The buffer layer 130 may include one of InGaAs, GaAs, GaP, InP, InGaP, GaSb, and InSb.

The channel layer 140 formed of a group III-V semiconductor may be epitaxially grown from the buffer layer 130 and may be a compound that includes at least one group III element and at least one group V element. The channel layer 140 may have a cubic-lattice structure, similarly to the buffer layer 130. The channel layer 140 may include one of InGaAs, GaAs, GaP, InP, InGaP, GaSb, and InSb. The channel layer 140 may include the same material as the buffer layer 130 or of a different material than the buffer layer 130.

Impurity regions 141 and 142 may respectively be formed under the source electrode 171 and the drain electrode 172. An ohmic contact may be formed between the channel layer 140 and each of the source electrode 171 and the drain electrode 172. The impurity regions 141 and 142 may be formed by using an ion implanting method.

The protection layer 145 that includes sulfur is formed on the channel layer 140. The protection layer 145 is a material layer formed by bonding sulfur with a dangling bond formed on outer regions of the channel layer 140. When supplying H₂S in a gas state onto the gate insulating layer 150 that covers the outer regions of the channel layer 140 where the dangling bond is formed, and rapidly annealing a chamber (not shown) including the resultant structure at a temperature in a range from about 300° C. to about 500° C., sulfur S of the H₂S is separated in an ionic state. The sulfur S in an ionic state passing through the gate insulating layer 150 combines with the dangling bond of the channel layer 140, and thus, a stable protection layer 145 is formed. The protection layer 145 removes the dangling bond, which is an interface defect formed on a surface of the channel layer 140.

The gate insulating layer 150 may include a high dielectric material. For example, the gate insulating layer 150 may include hafnium oxide or aluminum oxide. The gate insulating layer 150 may have a thickness in a range of about 10 Å to about 100 Å, so that the sulfur S may pass through the thin gate insulating layer 150 during the manufacturing process of the group III-V semiconductor transistor 100, which will be described below.

The gate electrode 160, the source electrode 171, and the drain electrode 172 may include metal materials.

In the group III-V semiconductor transistor 100 according to example embodiments, the stable protection layer 145 is formed by bonding the dangling bond on the surface of the channel layer 140 with the sulfur S of H₂S, and accordingly, an interface characteristic between the channel layer 140 of the group III-V semiconductor transistor 100 and the gate insulating layer 150 is improved. As a result, a switching characteristic of the group III-V semiconductor transistor 100 is improved.

FIG. 2 is a graph illustrating thin film characteristics of the gate insulating layer and the channel layer of the group III-V semiconductor transistor 100 according to example embodiments. Capacitance characteristics of the gate insulating layer and of the channel layer of the group III-V semiconductor transistor 100 were measured by respectively disposing the channel layer and the gate insulating layer between two electrodes. In this example, the channel layer is formed of InGaAs, and the gate insulating layer is formed of aluminum oxide with a thickness of 40 Å. A first curve C1 is a capacitance characteristic curve of the channel layer and the gate insulating layer of a transistor in which a solution that includes a sulfur component, such as (NH₄)₂S, is coated onto a surface of a group III-V channel layer by using a conventional method. A second curve C2 is a capacitance characteristic curve of the channel layer and the gate insulating layer of a transistor manufactured according to example embodiments.

Referring to FIG. 2, the second curve C2 has a reduced hysteresis when compared to the first curve C1. This reduced hysteresis denotes that the interface characteristic between the gate insulating layer 150 and the channel layer 140 is improved. The improvement in the interface characteristic shows that a stable protection layer 145 was formed by bonding sulfur with the dangling bond on the surface of the channel layer 140, and the use of an annealing process further improves the interface characteristic.

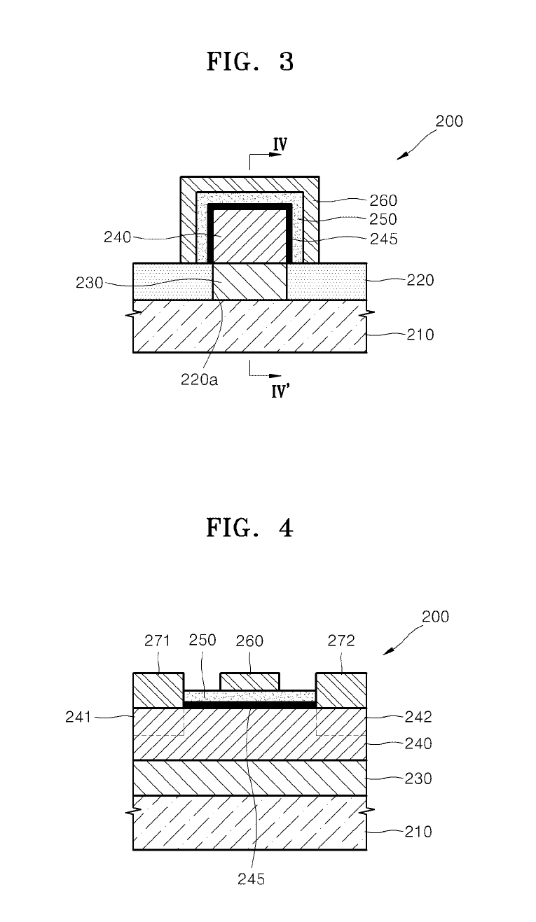

FIG. 3 is a schematic cross-sectional view of a group III-V semiconductor transistor 200 according to example embodiments. FIG. 4 is a cross-sectional view taken along line IV-IV′ of FIG. 3.

Referring to FIGS. 3 and 4, according to at least one example embodiment, an insulating layer 220 is formed on a substrate 210. A hole 220a is formed in the insulating layer 220. The hole 220a may be a slit having a long narrow cut in a given direction and exposes the substrate 210. A buffer layer 230 may be formed in the hole 220a, the buffer layer 230 being grown from the exposed substrate 210. A channel layer 240 formed of a group III-V semiconductor is formed on the buffer layer 230. A protection layer 245, a gate insulating layer 250, and a gate electrode 260 are sequentially formed on a top surface and on the side surfaces of the channel layer 240. A source electrode 271 and a drain electrode 272 that are separated from each other are formed at both sides of the channel layer 240.

The substrate 210 may be formed of, or include, silicon, which is mainly used in semiconductor processes. However, the example embodiment is not limited thereto, that is, the substrate 210 may include other semiconductor materials than silicon.

The insulating layer 220 may include an oxide or a nitride. For example, the insulating layer 220 may include silicon oxide SiOx or silicon nitride SiNx. In the case when the insulating layer 220 is formed of an oxide and the substrate 210 is formed of silicon, the insulating layer 220 may be formed by oxidizing the substrate 210.

The buffer layer 230 may be epitaxially grown from the surface of the substrate 210 that is exposed through the hole 220a to fill the hole 220a. The buffer layer 230 may have the same lattice structure as the substrate 210 and the channel layer 240, and mitigates a lattice mismatch between the substrate 210 and the channel layer 240. The substrate 210 may be a silicon substrate having a (100) surface, and the buffer layer 230 may also have a cubic-lattice structure similar to or the same as the silicon substrate 210. The buffer layer 230 may be formed of or include one of InGaAs, GaAs, GaP, InP, InGaP, GaSb, and InSb.

The channel layer 240 formed of or including a group III-V semiconductor may have a protruded fin shape. The group III-V semiconductor transistor 100 having the channel layer 240 is also referred to as a Fin field effect transistor (FinFET). The group III-V semiconductor channel layer 240 may be a compound that includes at least one group III element and at least one group V element. The group III-V semiconductor channel material may have the same crystal structure as silicon since the group III-V semiconductor channel material may be grown on the buffer layer 230. The substrate 210 may have a (100) surface, and the group III-V semiconductor channel layer 240 that is grown from the buffer layer 230 may include one of InGaAs, GaAs, GaP, InP, InGaP, GaSb, and InSb.

The channel layer 240 may have a width in a range of about 10 Å to about 20 Å, a height of approximately 50 Å, and a length of approximately 60 Å.

A protection layer 245 that includes sulfur is formed on the channel layer 240. The protection layer 245 is a material layer that is formed by combining sulfur with a dangling bond formed on an outer surface of the channel layer 240. When supplying H₂S in a gas state onto the gate insulating layer 250 that covers the outer regions of the channel layer 240 where the dangling bond is formed and rapidly annealing a chamber (not shown) including the resultant structure at a temperature in a range of about 300° C. to about 500° C., sulfur S of the H₂S is separated in an ion state. The sulfur S in an ionic state passing through the gate insulating layer 250 combines with the dangling bond of the channel layer 240, and thus, a stable protection layer 245 may be formed. The protection layer 245 removes the dangling bond which is an interfacial defect formed on a surface of the channel layer 240.

The gate insulating layer 250 may include a high dielectric material. For example, the gate insulating layer 250 may include hafnium oxide or aluminum oxide. The gate insulating layer 250 may have a thickness in a range of about 10 Å to about 100 Å, so that the sulfur S may pass through the thin gate insulating layer 250 when manufacturing the group III-V semiconductor transistor 200, which will be described below.

The gate electrode 260, the source electrode 271, and the drain electrode 272 may include metal materials.

Impurity regions 241 and 242 may be respectively formed under the source electrode 271 and the drain electrode 272. The impurity regions 241 and 242 may be formed, for example, by using an ion implanting method.

In the group III-V semiconductor transistor 200 according to example embodiments, the stable protection layer 245 is formed by bonding the dangling bond on the surface of the channel layer 240 with the sulfur S of H₂S, and accordingly, an interface characteristic between the channel layer 240 of the group III-V semiconductor transistor 200 and the gate insulating layer 250 is improved. As a result, a switching characteristic of the group III-V semiconductor transistor 200 is improved.

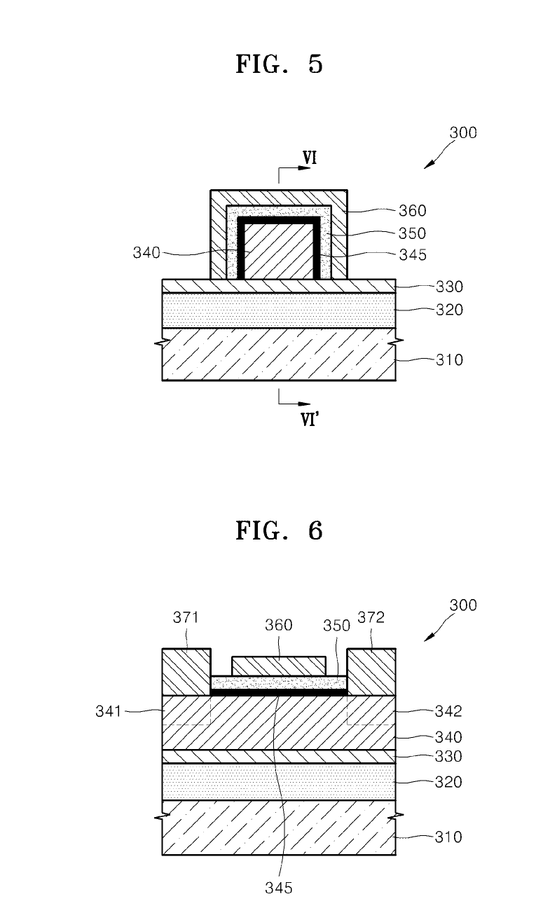

FIG. 5 is a schematic cross-sectional view of a group III-V semiconductor transistor 300 according to example embodiments. FIG. 6 is a cross-sectional view taken along line IV-IV′ of FIG. 5.

Referring to FIGS. 5 and 6, an insulating layer 320 is formed on a substrate 310. A buffer layer 330 that is grown from the substrate 310 may be formed on the insulating layer 320. The buffer layer 330 may be omitted. A channel layer 340 formed of a group III-V semiconductor is formed on the buffer layer 330. A protection layer 345, a gate insulating layer 350, and a gate electrode 360 are sequentially formed on a top surface and on the side surfaces of the channel layer 340. A source electrode 371 and a drain electrode 372 that are separated from each other are formed at both sides of the channel layer 340.

The substrate 310 may include silicon, which is mainly used in semiconductor processes. However, the example embodiment is not limited thereto. That is, the substrate 310 may include other semiconductor materials.

The insulating layer 320 may include an oxide or a nitride. For example, the insulating layer 320 may include silicon oxide SiOx or silicon nitride SiNx. In the case when the insulating layer 320 is formed of an oxide and the substrate 310 is formed of silicon, the insulating layer 320 may be formed by oxidizing the substrate 310.

The buffer layer 330 may be epitaxially grown from the substrate 310. The buffer layer 330 has the same lattice structure as the substrate 310 and the channel layer 340, and mitigates a lattice mismatch between the substrate 310 and the channel layer 340. The substrate 310 may be a silicon substrate having a (100) surface and the buffer layer 330 may also have a cubic-lattice structure like the silicon substrate 310. The buffer layer 330 may include one of InGaAs, GaAs, GaP, InP, InGaP, GaSb, and InSb.

The channel layer 340 formed of a group III-V semiconductor may have a protruded fin shape. The group III-V semiconductor transistor 300 having the channel layer 340 is also referred to as a FinFET. The group III-V semiconductor channel layer 340 may be a compound that includes at least one group III element and at least one group V element. The group III-V semiconductor channel material may have the same crystal structure as silicon since the group III-V semiconductor channel material may be grown on the buffer layer 330. The substrate 310 may have a (100) surface, and the group III-V semiconductor channel layer 340 that is grown from the buffer layer 330 may include one of InGaAs, GaAs, GaP, InP, InGaP, GaSb, and InSb.

The channel layer 340 may have a width in a range from about 10 Å to about 20 Å, a height of approximately 50 Å, and a length of approximately 60 Å.

A protection layer 345 that includes sulfur is formed on the channel layer 340. The protection layer 345 is a material layer that is formed by combining sulfur with a dangling bond formed on an outer surface of the channel layer 340. When supplying H₂S in a gas state onto the gate insulating layer 350 that covers the outer regions of the channel layer 140 where the dangling bond is formed and rapidly annealing a chamber (not shown) including the resultant structure at a temperature in a range of about 300° C. to about 500° C., sulfur S of H₂S is separated in an ionic state. The sulfur S in an ionic state passing through the gate insulating layer 350 combines with the dangling bond, and thus, a stable protection layer 345 may be formed. The protection layer 345 removes the dangling bond which is an interfacial defect formed on a surface of the channel layer 340.

The gate insulating layer 350 may include a high dielectric material. For example, the gate insulating layer 350 may include hafnium oxide or aluminum oxide. The gate insulating layer 350 may have a thickness in a range of about 10 Å to about 100 Å, so that the sulfur S may pass through the thin gate insulating layer 350 when manufacturing the group III-V semiconductor transistor 300, which will be described below.

The gate electrode 360, the source electrode 371, and the drain electrode 372 may include metal materials.

Impurity regions 341 and 342 may be respectively formed under the source electrode 371 and the drain electrode 372. The impurity regions 341 and 342 may be formed by using an ion implanting method.

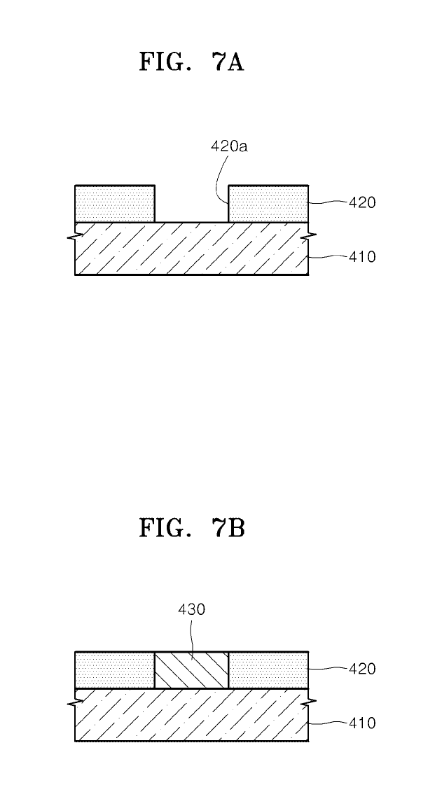

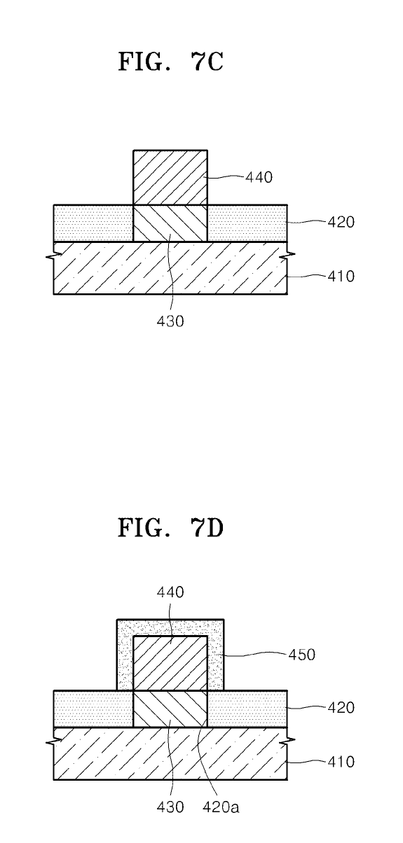

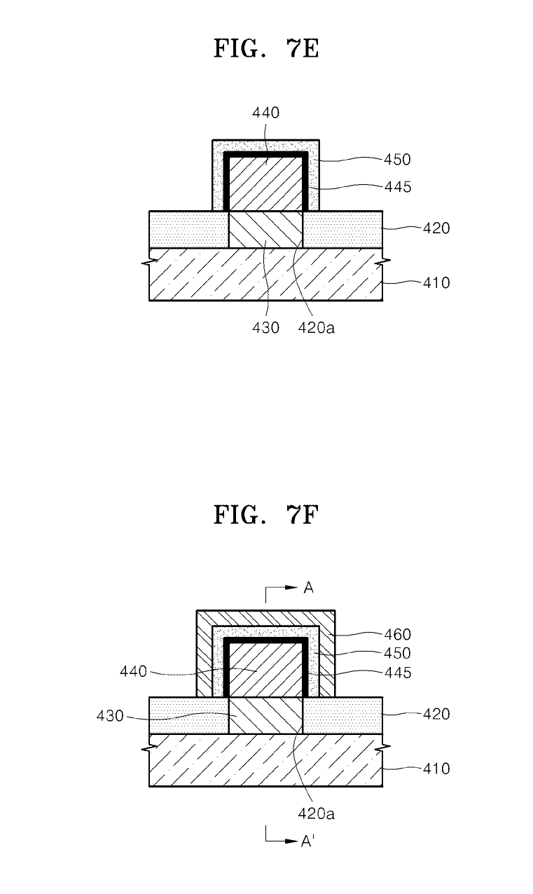

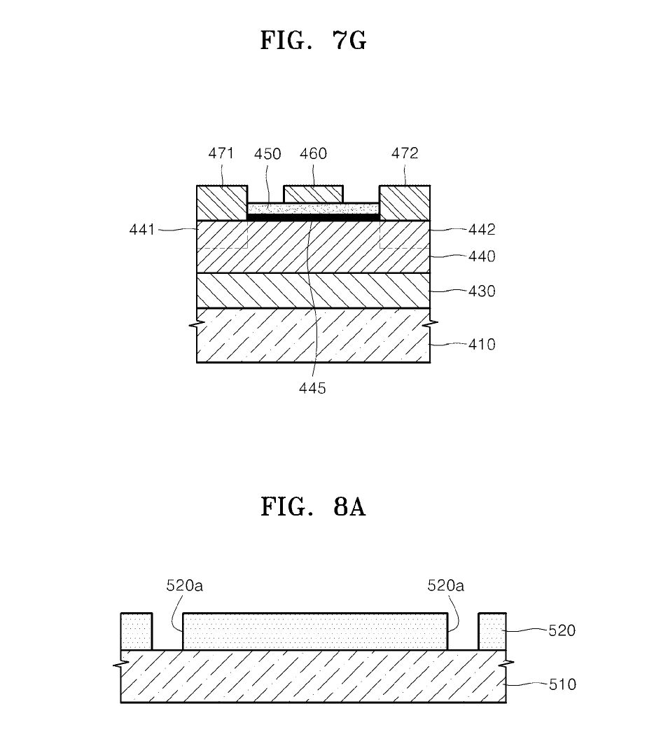

FIGS. 7A through 7G are cross-sectional views sequentially showing a method of manufacturing a group III-V semiconductor transistor according to example embodiments. The method may be a method of manufacturing the group III-V semiconductor transistor 200 of FIGS. 3 and 4.

Referring to FIG. 7A, an insulating layer 420 is formed on a substrate 410. The substrate 410 may include silicon or other semiconductor materials. Hereinafter, the following descriptions will be made with the substrate 410 formed of silicon having a (100) surface as an example.

The insulating layer 420 may include an oxide or nitride. For example, the insulating layer 420 may include silicon oxide SiOx or silicon nitride SiNx.

A portion of a surface of the substrate 410 is exposed by forming a hole 420a in the insulating layer 420. The hole 420a may be a slit having a long narrow cut in a given direction. The hole 420a may have a width in a range from about 10 Å to about 20 Å and a length of approximately 60 Å.

Referring to FIG. 7B, a buffer layer 430 may be epitaxially grown from the exposed surface of the substrate 410. The buffer layer 430 may have the same crystal structure as the crystal structure of the substrate 410. The buffer layer 430 may be formed by using a metal-organic chemical vapor deposition (MOCVD) method that uses, for example, a metal-organic gas as a source gas. The buffer layer 430 may include one of InGaAs, GaAs, GaP, InP, InGaP, GaSb, and InSb.

In FIG. 7B, an upper surface of the buffer layer 430 may have the same height as an upper surface of the insulating layer 420. However, the example embodiment is not limited thereto. For example, the upper surface of the buffer layer 430 may be higher or lower than the upper surface of the insulating layer 420. A chemical-mechanical polishing (CMP) method may be employed so that the buffer layer 430 has the same height as the height of the insulating layer 420.

Referring to FIG. 7C, a group III-V semiconductor layer 440 is vertically grown on the buffer layer 430. The group III-V semiconductor layer 440 may be a compound that includes at least one group III element and at least one group V element. For example, the group III-V semiconductor layer 440 may have the same crystal structure as silicon since the group III-V semiconductor layer 440 is grown on the buffer layer 430. The group III-V semiconductor layer 440 may include one of InGaAs, GaAs, GaP, InP, InGaP, GaSb, and InSb. The group III-V semiconductor layer 440 may have a height of approximately 50 Å. The group III-V semiconductor layer 440 may have a fin shape. Hereinafter, the group III-V semiconductor layer 440 may be referred to as a channel layer 440.

Referring to FIG. 7D, a gate insulating layer 450 that covers a top surface and the side surfaces of the channel layer 440 may be formed on the insulating layer 420. The gate insulating layer 450 may include a high dielectric material, for example, hafnium oxide or aluminum oxide, by using a deposition method. The gate insulating layer 450 may have a thickness in a range from about 10 Å to about 100 Å.

Referring to FIG. 7E, the substrate 410 may be annealed under a sulfur atmosphere. The substrate 410 is placed in a chamber (not shown), H₂S as a source of sulfur gas is supplied into the chamber, and nitrogen gas or argon gas is used as a carrier gas. H₂S is supplied in a range from about 1 vol % to about 10 vol % of the carrier gas, and the chamber is maintained at a pressure in a range from about 1 torr to about 500 torr. The annealing may be performed for about 5 minutes to about 30 minutes at a temperature in a range from about 300° C. to about 500° C. The concentration of sulfur may be controlled by the supplied amount of H₂S and the process temperature. When the annealing temperature exceeds 500° C., the characteristics of a transistor may be degraded. When the annealing temperature is below 300° C., the decomposition of H₂S may be delayed, and thus, the formation of a protection layer 445 which will be described below may be difficult. H₂S supplied into the chamber is decomposed to hydrogen and a sulfur ion, and the sulfur ion enters into an interface between the gate insulating layer 450 and the channel layer 440 passing through the gate insulating layer 450. The sulfur ion that enters into the interface forms a covalent bond with a dangling bond on an outer surface of the channel layer 440, and thus, a stable protection layer 445 is formed. Through the combination of the sulfur and the annealing, an interface characteristic between the channel layer 440 and the gate insulating layer 450 is improved.

Referring to FIG. 7F, a gate electrode 460 is formed on the gate insulating layer 450. The gate electrode 460 may include a metal material by using a deposition method, for example, a sputtering method.

FIG. 7G shows a cross-sectional view taken along line A-A′ of FIG. 7F. Referring to FIG. 7G, both edges of the channel layer 440 are exposed by sequentially etching the gate insulating layer 450 and the protection layer 445 on both edges of the channel layer 440. A source electrode 471 and a drain electrode 472 that are separated from the gate electrode 460 are respectively formed on both exposed edges of the channel layer 440. The method of forming the source electrode 471 and the drain electrode 472 may be a patterning method that is well known in semiconductor processing, and thus, the detailed description is omitted.

Before forming the source electrode 471 and the drain electrode 472, impurity regions 441 and 442 may be respectively formed on regions of the channel layer 440 where the source electrode 471 and the drain electrode 472 are to be formed thereon. The impurity regions 441 and 442 may be formed by using an ion implanting method. The impurity regions 441 and 442 may be formed for forming an ohmic contact between the source and drain electrodes 471 and 472 and the channel layer 440.

The forming of the source electrode 471 and the drain electrode 472 may be performed prior to the forming of the gate electrode 460.

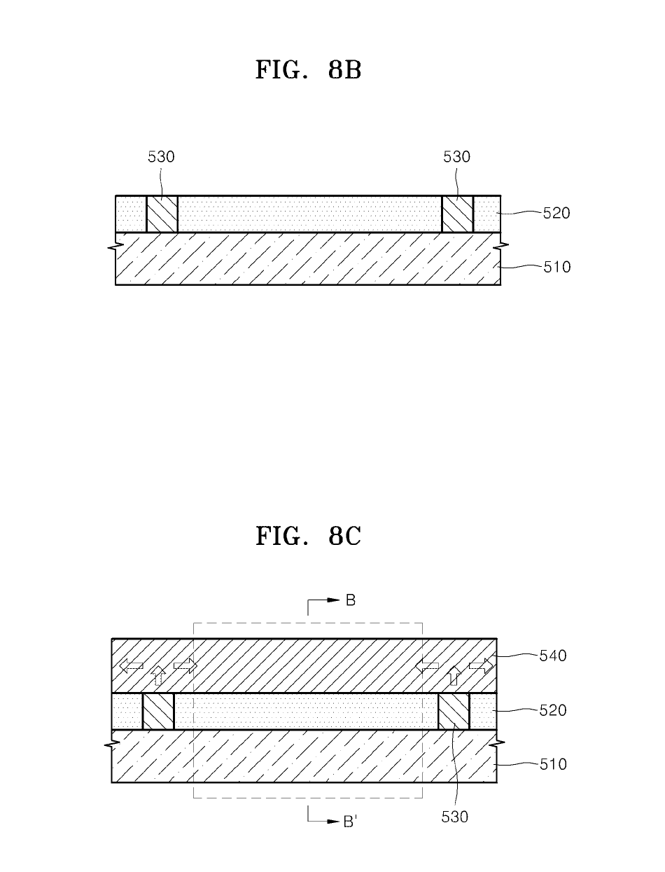

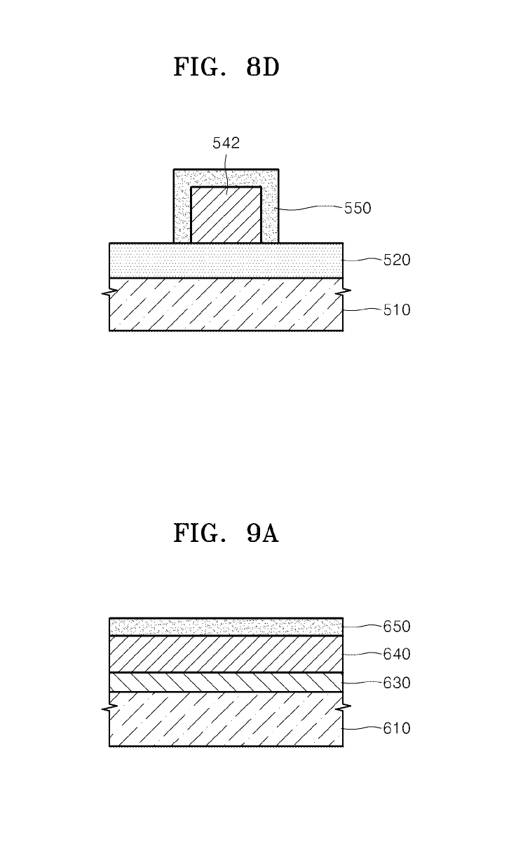

FIGS. 8A through 8D are cross-sectional views sequentially showing a method of manufacturing a group III-V semiconductor transistor according to example embodiments. This method may be a method of manufacturing the group III-V semiconductor transistor 300 of FIGS. 5 and 6.

Referring to FIG. 8A, an insulating layer 520 is formed on a substrate 510. The substrate 510 may include silicon or other semiconductor materials. Hereinafter, the following descriptions will be made with the substrate 510 formed of silicon having a (100) surface as an example.

The insulating layer 520 may include an oxide or nitride. For example, the insulating layer 520 may include silicon oxide SiOx or silicon nitride SiNx.

A portion of a surface of the substrate 510 is exposed by forming a hole 520a in the insulating layer 520. The hole 520a may be a slit having a long narrow cut in a given direction.

Referring to FIG. 8B, a buffer layer 530 may be epitaxially grown from the exposed surface of the substrate 510. The buffer layer 530 may have the same crystal structure as the crystal structure of the substrate 510. The buffer layer 530 may be formed by using a MOCVD method that uses, for example, a metal-organic gas as a source gas. The buffer layer 530 may include one of InGaAs, GaAs, GaP, InP, InGaP, GaSb, and InSb.

Referring to FIG. 8C, a group III-V semiconductor layer 540 is vertically grown on the buffer layer 530. The group III-V semiconductor layer 540 may be laterally grown on the insulating layer 520 after being vertically grown from the buffer layer 530. In FIG. 8C, arrows indicate growing directions.

The group III-V semiconductor layer 540 may be a compound that includes at least one group III element and at least one group V element. For example, the group III-V semiconductor layer 540 may have the same crystal structure as silicon since the group III-V semiconductor layer 540 can be grown on the buffer layer 530. The group III-V semiconductor layer 540 may include one of InGaAs, GaAs, GaP, InP, InGaP, GaSb, and InSb. The group III-V semiconductor layer 540 may be formed to have a height of approximately 50 Å.

The example embodiment is not limited thereto. For example, after vertically growing the buffer layer 530 and horizontally growing the semiconductor layer 540 on the insulating layer 520, the group III-V semiconductor layer 540 may be vertically grown on the buffer layer 530 (see FIG. 5).

Next, as shown in FIG. 8C, a structure in which the insulating layer 520 and the group III-V semiconductor layer 540 are sequentially formed on the substrate 510 may be obtained when the structure is quadrangularly cut as indicated by the dotted lines by using various cutting methods. The buffer layer 530 (see FIG. 5) may further be formed between the insulating layer 520 and the group III-V semiconductor layer 540.

Referring to FIG. 8D, a group III-V semiconductor channel layer 542 having a pin shape may be formed by patterning the group III-V semiconductor layer 540. The group III-V semiconductor channel layer 542 may have a width in a range from about 10 Å to about 20 Å and a length of approximately 60 Å. FIG. 8D shows a cross-sectional view taken along line B-B′ of the structure of FIG. 8C.

A gate insulating layer 550 that covers the group III-V semiconductor channel layer 542 is formed on the insulating layer 520. The gate insulating layer 550 may include a high dielectric material, for example, hafnium oxide or aluminum oxide, by using a general deposition method. The gate insulating layer 550 may have a thickness in a range from about 10 Å to about 100 Å.

Processes of forming a protection layer and electrodes can be understood from the processes described with reference to FIGS. 7D through 7F, and thus, the detailed description will be omitted.

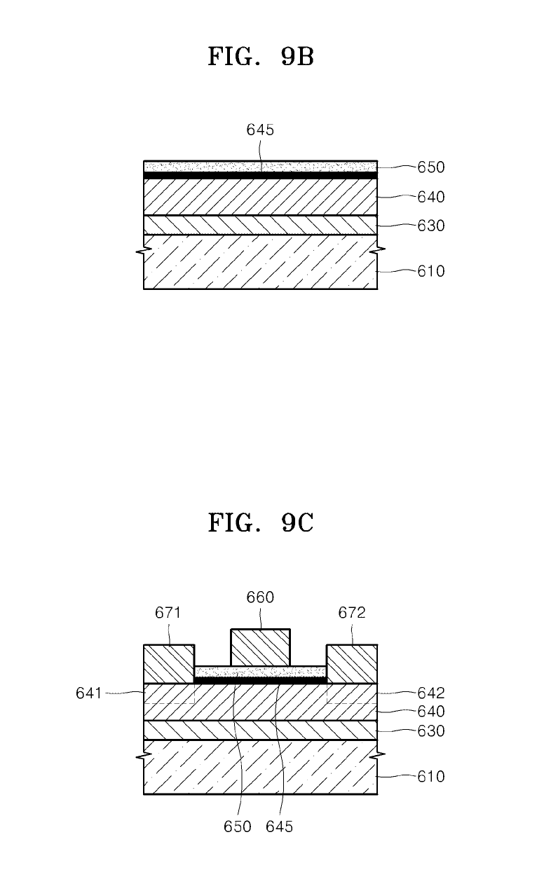

FIGS. 9A through 9C are cross-sectional views sequentially showing a method of manufacturing a group III-V semiconductor transistor according to example embodiments.

Referring to FIG. 9A, a buffer layer 630 is formed on a substrate 610. The substrate 610 may include silicon or other semiconductor materials. Hereinafter, the following descriptions will be made with the substrate 610 formed of silicon having a (100) surface as an example.

The buffer layer 630 may be epitaxially grown on the substrate 610. The buffer layer 630 may have the same crystal structure as the crystal structure of the substrate 610. The buffer layer 630 may be formed by using a MOCVD method that uses, for example, a metal-organic gas as a source gas. The buffer layer 630 may include one of InGaAs, GaAs, GaP, InP, InGaP, GaSb, and InSb.

A group III-V semiconductor layer 640 is vertically grown on the buffer layer 630. The group III-V semiconductor layer 640 may be a compound that includes at least one group III element and at least one group V element. For example, the group III-V semiconductor layer 640 may have the same crystal structure as silicon since the group III-V semiconductor layer 640 is grown on the buffer layer 630. The group III-V semiconductor layer 640 may include one of InGaAs, GaAs, GaP, InP, InGaP, GaSb, and InSb. The group III-V semiconductor layer 640 may have a height of approximately 50 Å. Hereinafter, the group III-V semiconductor layer 640 may be referred to as a channel layer 640.

A gate insulating layer 650 is formed on the channel layer 640. The gate insulating layer 650 may include a high dielectric material, for example, hafnium oxide or aluminum oxide, by using a general deposition method. The gate insulating layer 650 may have a thickness in a range of about 10 Å to about 100 Å.

Referring to FIG. 9B, the substrate 610 is annealed under a sulfur atmosphere. The substrate 610 is placed in a chamber (not shown), H₂S as a source of sulfur gas is supplied into the chamber, and nitrogen gas or argon gas is used as a carrier gas. H₂S is supplied in a range from about 1 vol % to about 10 vol % of the carrier gas, and the chamber is maintained at a pressure in a range from about 1 torr to about 500 torr. The annealing may be performed for about 5 minutes to about 30 minutes at a temperature in a range from about 300° C. to about 500° C. The concentration of sulfur may be controlled by the supplied amount of H₂S and the process temperature. When the annealing temperature exceeds 500° C., the characteristics of a transistor may be degraded. When the annealing temperature is below 300° C., the decomposition of H₂S may be delayed, and thus, the formation of a protection layer 645 which will be described below may be difficult. H₂S supplied into the chamber is decomposed to hydrogen and a sulfur ion, and the sulfur ion passing through the gate insulating layer 650 enters into an interface between the gate insulating layer 650 and the channel layer 640. The sulfur ion that enters into the interface forms a covalent bond with a dangling bond on an outer surface of the channel layer 640, and thus, a stable protection layer 645 is formed. Through the combination of sulfur supply and annealing, an interface characteristic between the channel layer 640 and the gate insulating layer 650 is improved.

Referring to FIG. 9C, a gate electrode 660 is formed on the gate insulating layer 650. The gate electrode 660 may include a metal material by using a deposition method, for example, a sputtering method.

Both edges of the channel layer 640 are exposed by sequentially removing regions of the gate insulating layer 650 and the protection layer 645 that are separated from the gate electrode 660. A source electrode 671 and a drain electrode 672 are respectively formed on both exposed edges of the channel layer 640.

Before forming the source electrode 671 and the drain electrode 672, impurity regions 641 and 642 may be respectively formed on regions where the source electrode 671 and the drain electrode 672 are formed thereon. The impurity regions 641 and 642 may be formed by using an ion implanting method. The impurity regions 641 and 642 are formed for forming an ohmic contact between the source and drain electrodes 671 and 672 and the channel layer 640.

The forming of the source electrode 671 and the drain electrode 672 may be performed prior to the forming of the gate electrode 660.

As described above, according to example embodiments, a stable protection layer is formed by combining a dangling bond present on a surface of a channel layer with sulfur of H₂S. Therefore, an interface characteristic between a gate insulating layer and a channel layer is improved, and accordingly, a switching characteristic of a transistor is improved.

While one or more example embodiments have been described with reference to the figures, it will be understood by those of ordinary skill in the art that various changes in form and details may be made therein without departing from the spirit and scope of the example embodiments as defined by the following claims.

What is claimed is:

1. A transistor comprising:
a substrate;
a group III-V semiconductor channel layer on the substrate;
a protection layer on the group III-V semiconductor channel layer, the protection layer including sulfur;
a gate insulating layer covering the protection layer;
a gate electrode on the gate insulating layer; and
a source electrode and a drain electrode respectively connected to separate sides of the group III-V semiconductor channel layer,
wherein the protection layer includes a combination of a dangling bond of the group III-V semiconductor channel layer and the sulfur.

2. The transistor of claim 1, wherein the group III-V semiconductor channel layer includes one of InGaAs, GaAs, InP, GaSb, and InSb.

3. The transistor of claim 1, wherein the dangling bond is on a surface of the group III-V semiconductor channel layer.

4. The transistor of claim 1, wherein the gate insulating layer comprises hafnium oxide or aluminum oxide.

5. The transistor of claim 4, wherein the gate insulating layer has a thickness in a range of about 10 Å to about 100 Å.

6. The transistor of claim 1, wherein the group III-V semiconductor channel layer has a fin shape.

7. The transistor of claim 6, further comprising:
an insulating layer on the substrate, the insulating layer having an opening exposing a surface of the substrate; and
a buffer layer filling the opening,
wherein the group III-V semiconductor channel layer is vertically formed on the buffer layer, and the protection layer, the gate insulating layer, and the gate electrode surround a top surface and side surfaces of the group III-V semiconductor channel layer.

8. The transistor of claim 6, further comprising an insulating layer and a buffer layer between the substrate and the group III-V semiconductor channel layer,
wherein the protection layer, the gate insulating layer, and the gate electrode surround a top surface and side surfaces of the group III-V semiconductor channel layer.

9. A method of manufacturing a transistor, the method comprising:
forming a group III-V semiconductor channel layer on a substrate;
forming a gate insulating layer that covers the group III-V semiconductor channel layer;
forming a protection layer including sulfur between the group III-V semiconductor channel layer and the gate insulating layer by annealing the substrate under a sulfur atmosphere;
forming a gate electrode on the gate insulating layer; and
forming a source electrode and a drain electrode that respectively contact separate sides of the group III-V semiconductor channel layer.

10. The method of claim 9, wherein the group III-V semiconductor channel layer includes one of InGaAs, GaAs, InP, GaSb, and InSb.

11. The method of claim 9, wherein the gate insulating layer comprises hafnium oxide or aluminum oxide.

12. The method of claim 9, wherein the gate insulating layer has a thickness in a range of about 10 Å to about 100 Å.

13. The method of claim 9, wherein the forming of the protection layer comprises annealing the substrate in a chamber into which an H₂S gas and a carrier gas are supplied.

14. The method of claim 9, wherein the forming of the protection layer comprises combining sulfur that is separated from H₂S gas and that passes through the gate insulating layer with a dangling bond of the group III-V semiconductor channel layer.

15. The method of claim 9, wherein the group III-V semiconductor channel layer has a fin shape.

16. The method of claim 15, further comprising:
forming an insulating layer on the substrate to have an opening that exposes the substrate; and
forming a buffer layer that fills the opening,
wherein the forming of the group III-V semiconductor channel layer comprises vertically and epitaxially growing the group III-V semiconductor channel layer from the buffer layer, and
the protection layer, the gate insulating layer, and the gate electrode surround a top surface and side surfaces of the group III-V semiconductor channel layer.

17. The method of claim 15, further comprising forming an insulating layer and a buffer layer between the substrate and the group III-V semiconductor channel layer,
wherein the protection layer, the gate insulating layer, and the gate electrode surround a top surface and side surfaces of the group III-V semiconductor channel layer.
